(19) United States
(12) Patent Application Publication
(10) Pub. No.: US 2009/0016022 A1
(43) Pub. Date: Jan. 15, 2009

(54) SEMICONDUCTOR MODULE

(75) Inventors: Hun HAN, Chungcheongnam-do (KR); Dong-Chun LEE, Chungcheongnam-do (KR); Hyo-Jae BANG, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 12/172,133

(22) Filed: Jul. 11, 2008

(30) Foreign Application Priority Data
Jul. 11, 2007 (KR) 2007-69386

(51) Int. Cl. H05K 7/20

(52) U.S. Cl. 361/700

(57) ABSTRACT

A semiconductor module includes a base plate, a circuit substrate coupled to a side face of the base plate, a first semiconductor package mounted on the circuit substrate and a radiation channel portion inside the base plate. The radiation channel portion includes at least one heat pipe containing a working fluid. The at least one heat pipe containing the working fluid is configured to transfer heat generated by the first semiconductor package. Thus, the radiation channel portion may provide an efficient and reliable semiconductor module having improved heat transfer and radiation performance.

### CROSS-REFERENCE TO RELATED APPLICATIONS

This application claims priority under 35 USC § 119 to Korean Patent Application No. 2007-69386, filed on Jul. 11, 2007, the contents of which are herein incorporated by reference in their entirety.

### SUMMARY

Example embodiments of the present invention relate to semiconductor modules. More particularly, example embodiments of the present invention relate to a semiconductor module including a plurality of densely-mounted semiconductor packages.

Example embodiments of the present invention can be generally characterized as capable of providing a semiconductor module with improved heat transfer and radiation performance.

One example embodiment described herein can be described as a semiconductor module including a base plate, a circuit substrate coupled to a side face of the base plate, a first semiconductor package mounted on the circuit substrate and a radiation channel portion inside the base plate. The radiation channel portion may include at least one heat pipe containing a working fluid. The at least one heat pipe containing the working fluid may be configured to transfer heat generated by the first semiconductor package. Thus, the radiation channel portion may provide an efficient and reliable semiconductor module having improved heat transfer and radiation performance.

### BRIEF DESCRIPTION OF THE DRAWINGS

The above and other embodiments of the present invention will become more apparent with reference to the accompanying drawings.

FIG. 1 is a perspective view illustrating a semiconductor module in accordance with a first example embodiment of the present invention;

FIG. 2 is a cross-sectional view taken along a line II-II′ in FIG. 1;

FIG. 3 is a plan view illustrating the radiation channel portion of the semiconductor module of FIG. 1;

FIG. 4 is a cross-sectional view taken along a line IV-IV′ of FIG. 3, in accordance with one example embodiment of the present invention;

FIG. 5 is a cross-sectional view taken along a line IV-IV′ of FIG. 3, in accordance with another example embodiment of the present invention;

FIG. 6 is a plan view illustrating a radiation channel portion of a semiconductor module in accordance with a second example embodiment of the present invention;

FIG. 7 is a plan view illustrating a radiation channel portion of a semiconductor module in accordance with a third example embodiment of the present invention;

FIG. 8 is a plan view illustrating a radiation channel portion of a semiconductor module in accordance with a fourth example embodiment of the present invention;

FIG. 9 is a plan view illustrating a radiation channel portion of a semiconductor module in accordance with a fifth example embodiment of the present invention;

FIG. 10 is a plan view illustrating a radiation channel portion of a semiconductor module in accordance with a sixth example embodiment of the present invention;

FIG. 11 is a cross-sectional view illustrating a semiconductor module in accordance with a seventh example embodiment of the present invention;

FIG. 12 is a cross-sectional view illustrating a semiconductor module in accordance with an eighth example embodiment of the present invention; and

FIG. 13 is a cross-sectional view illustrating a semiconductor module in accordance with a ninth example embodiment of the present invention.

### DETAILED DESCRIPTION

Example embodiments of the present invention are described more fully hereinafter with reference to the accompanying drawings. These embodiments may, however, be realized in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### EMBODIMENT 1

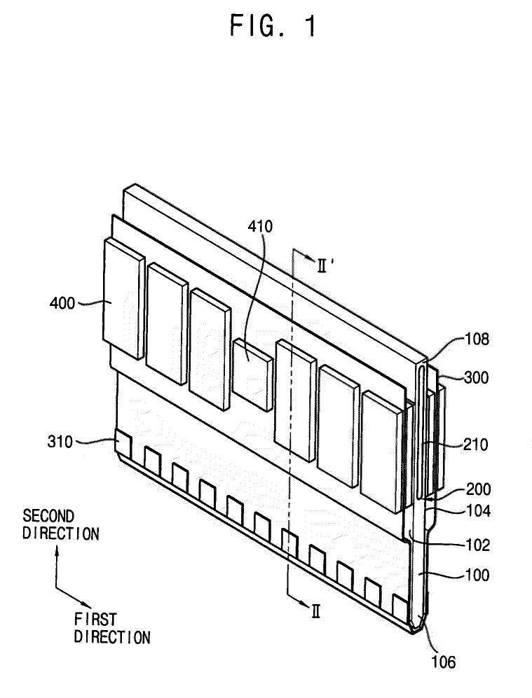

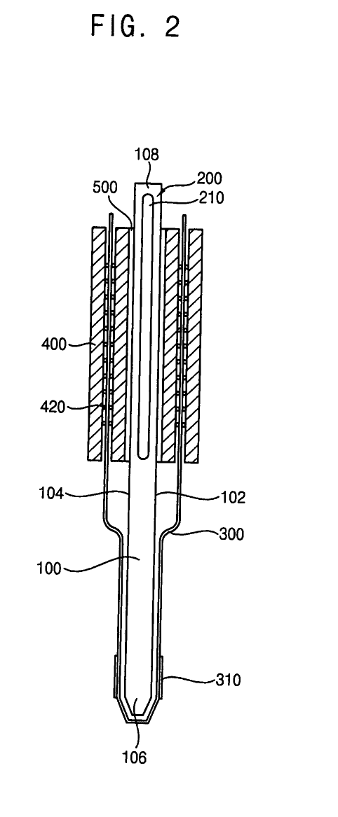

FIG. 1 is a perspective view illustrating a semiconductor module in accordance with a first example embodiment of the present invention. FIG. 2 is a cross-sectional view taken along a line II-II′ in FIG. 1.

Referring to FIGS. 1 and 2, a semiconductor module 10 includes a base plate 100, a radiation channel portion 200 formed inside the base plate 100, a circuit substrate 300 adhered to the base plate 100 and a plurality of semiconductor packages 400 and 410 mounted on the circuit substrate 300.

In an example embodiment, the base plate 100 may extend in a first direction. The base plate 100 may have a rectangular shape, a square shape or the like. The base plate 100 may have a first side face 102 and a second side face 104 opposite the first side face 102. The base plate 100 may also have a first side portion 106 and a second side portion 108 opposite the first side portion 106.

In one embodiment, the base plate 100 may include a thermally conductive metal such as aluminum, gold, etc. In another embodiment, the base plate 100 may include a thermally conductive plastic or a thermally conductive material such as a carbon substrate.

The radiation channel portion 200 is formed inside the base plate 100 and is positioned between the first side face 102 and the second side face 104. The radiation channel portion 200 may include a plurality of heat pipes 210 extending in a second direction perpendicular to the first direction.

Each of the heat pipes 210 may be a hermetically sealed chamber or tube. In one embodiment, a vacuum may be formed within each of the heat pipes 210. In one embodiment, a working fluid may be injected into each of the heat pipes 210. For example, the working fluid may include distilled water, ethanol, methanol, ammonia, acetone, etc. In one embodiment, nanoparticles may be provided within each of the heat pipes 210, in addition to the working fluid.

The working fluid is repeatedly evaporated and condensed by heat that is transferred from the semiconductor packages 400 and 410 to the base plate 100. Each of the heat pipes 210 may transfer the heat along an extending direction of the heat pipes 210 using latent heat owing to a phase change of evaporation and condensation of the working fluid.

The circuit substrate 300 is adhered to the first and second side faces 102 and 104 of the base plate 100. In one embodiment, the circuit substrate 300 may be a flexible printed circuit board (FPCB) in which an entirety thereof is flexible. In another embodiment, the circuit substrate 300 may be a rigid-flex printed circuit board in which only certain areas thereof are flexible. The circuit substrate 300 may have the flexible circuit structure. The flexible circuit structure may be made relatively flexible in certain areas (e.g., to allow conformability to required shapes or bends) and relatively rigid in other areas (e.g., to provide rigid and planar mounting surfaces).

Relatively rigid portions of the circuit substrate 300 may be evenly adhered to the first and second side faces 102 and 104 of the base plate 100. Relatively flexible portions of the circuit substrate 300 may be wound around the first side portion 106 of the base plate 100. In one embodiment, the relatively flexible portions of the circuit substrate 300 may be conformally wound around the first side portion 106 of the base plate 100.

A plurality of first contacts 310 may be formed on the circuit substrate 300. The first contacts 310 may be positioned adjacent to the first side portion 106 of the base plate 100. The first contacts 310 may be arranged in the first direction. The first contacts 310 may be spaced apart from one another.

The first side portion 106 of the base plate 100 may be inserted into a socket of a circuit board (not illustrated) where the semiconductor module 10 is mounted. The socket of the circuit board may have a female connector configured to contact the first contacts 310. Accordingly, the semiconductor module 10 may be electrically connected to the circuit board by the first contacts 310.

A plurality of the semiconductor packages 400 and 410 may be mounted on a surface or both surfaces of the circuit substrate 300. For example, the semiconductor packages 400 and 410 may include at least one of a ball grid array (BGA) package, a chip scale package (CSP), a multi-chip package (MCP), or the like.

In an example embodiment, semiconductor packages 400 (i.e., “first semiconductor packages”) may be provided as CSPs and semiconductor packages 410 (i.e., second semiconductor packages”) may be provided as advanced memory buffers (AMB). The first and second semiconductor packages 400 and 410 may be mounted in the first direction on both surfaces of the circuit substrate 300. In one embodiment, the second semiconductor package 410 may be arranged between the first semiconductor packages 400. The first and second semiconductor packages 400 and 410 may be electrically connected to the circuit substrate 300 by a plurality of second contacts 420.

In one embodiment, the semiconductor module 10 may further include additional semiconductor packages that are additionally stacked on outermost surfaces of the first and second semiconductor packages 400 and 410. Accordingly, an additional circuit substrate may be additionally adhered to the outermost semiconductor packages 400 and 410, and the additional semiconductor packages may be mounted on a surface or both surfaces of the additional circuit substrate.

A heat transfer layer 500 is disposed between the base plate 100 and the semiconductor packages 400 and 410 facing the base plate 100. The semiconductor packages 400 and 410 may be adhered to the first and second side faces 102 and 104 of the base plate 100 by the heat transfer layer 500.

In one embodiment, the heat transfer layer 500 may include a thermal interface material (TIM). The TIM may reduce the thermal resistance of the interface between the base plate 100 and the semiconductor packages 400 and 410, through which heat generated from the semiconductor packages 400 and 410 is transferred to the base plate 100, and provide adhesion to the interface. Examples of the TIM may be radiation grease, radiation bond, or the like or a combination thereof.

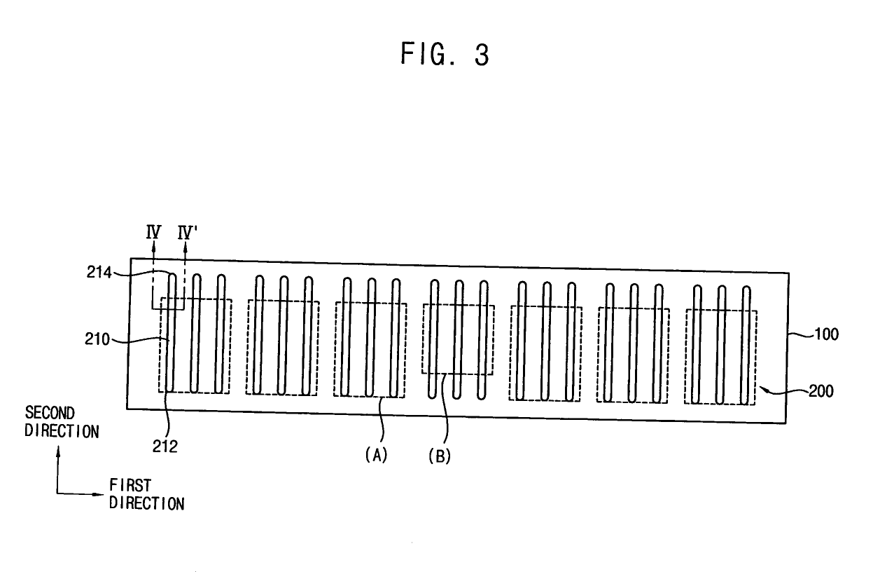

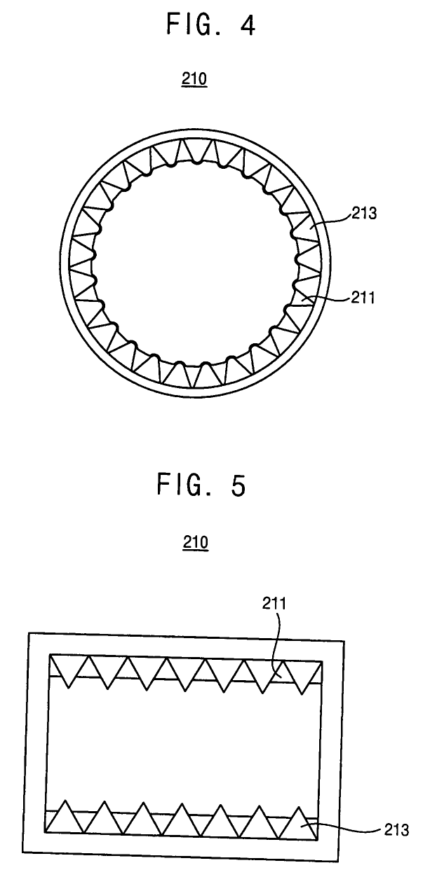

FIG. 3 is a plan view illustrating the radiation channel portion of the semiconductor module of FIG. 1. FIG. 4 is a cross-sectional view taken along a line IV-IV′ of FIG. 3, in accordance with one example embodiment of the present invention. FIG. 5 is a cross-sectional view taken along a line IV-IV′ of FIG. 3, in accordance with another example embodiment of the present invention. In FIG. 3, region (A) represents a region where the first semiconductor package 400 (e.g., a CSP) is mounted and region (B) represents a region where the second semiconductor package 410 (e.g., an AMB) is mounted.

Referring to FIG. 3, the radiation channel portion 200 positioned between the first side face 102 and the second side face 104 inside the base plate 100 includes a plurality of the heat pipes 210. The heat pipes 210 are arranged in the first direction. The heat pipes 210 are spaced apart from one another. Each heat pipe 210 extends in the second direction.

Referring to FIG. 4, the heat pipes 210 may have a circular or elliptical profile, or the like. In one embodiment, a plurality of ribs 213 may be formed on an inner peripheral surface of each of the heat pipes 210 to define a plurality of grooves therebetween. The grooves may extend in a longitudinal direction (second direction) of the heat pipes 210. The ribs 213 may be formed along an inner circumference of each of the heat pipes 210. In one embodiment, the grooves may be spaced apart by a predetermined distance from one another. In another embodiment, the grooves may be continuously formed along an inner circumference of each of the heat pipes 210.

In one embodiment, each of the grooves defined by ribs 213 may have a polygonal profile resembling a triangle, a tetragon, or the like. In another embodiment, each of the grooves defined by ribs 213 may have a curved profile resembling an arc, or the like. It will be appreciated, however, that the shapes of the grooves defined by ribs 213 and the distances of the grooves defined by ribs 213 may be varied as desired.

Referring to FIG. 5, each of the heat pipes 210 may have a polygonal profile such as a rectangle. In one embodiment, a plurality of ribs 213 may be formed on an inner peripheral surface of each of the heat pipes 210 having the rectangular profile. In another embodiment, the ribs 213 may be formed on one or two inner surfaces of each of the heat pipes 210. Alternatively, the ribs 213 may be formed on the entire inner peripheral surface of each of the heat pipes 210.

In some embodiments of present invention, the working fluid 211 injected into each of the heat pipes 210 due to capillary action induced by grooves defined between adjacent ones of the ribs 213. Accordingly, the working fluid 211 may be uniformly distributed over the entire inner peripheral surface of each of the heat pipes 210 against the force of gravity.

Heat that is generated from the semiconductor packages 400 and 410 is transferred to the base plate 100. Heat is then transferred from the base plate 100 to the working fluid 211 provided inside each of the heat pipes 210. The working fluid 211 is then evaporated by the heat that is transferred thereto. The evaporated working fluid 211 moves along the longitudinal direction (second direction) of the grooves 213 due to a pressure gradient inside each of the heat pipes 210.

The evaporated working fluid 211 moves to a first end portion 214 from a second end portion 212 of each of the heat pipes 210 along the second direction. Then, the evaporated working fluid 211 is condensed in the first end portion 214 of each of the heat pipes 210 due to a temperature difference. The condensed working fluid 211 then moves from the first end portion 214 to the second end portion 212 of each of the heat pipes 210 due to a pressure gradient inside each of the heat pipes 210. As a result, heat that is generated from the semiconductor packages 400 and 410 can be effectively dissipated.

### EMBODIMENT 2

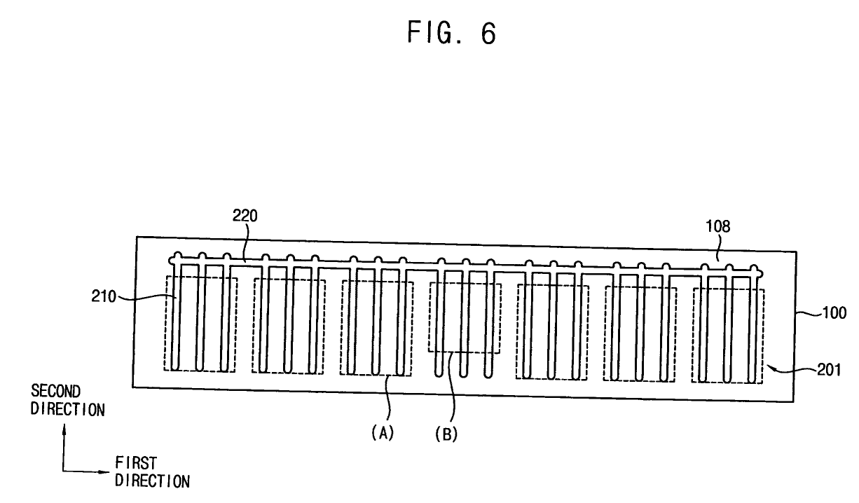

FIG. 6 is a plan view illustrating a radiation channel portion of a semiconductor module in accordance with a second example embodiment of the present invention.

The semiconductor module of the present embodiment may be substantially the same as in Embodiment 1, except for the above-described radiation channel portion 200. Thus, the same reference numerals will be used to refer to the same or similar parts as those described in Embodiment 1, and any further explanation concerning the above-described elements will be omitted.

Referring to FIG. 6, a radiation channel portion 201 of a semiconductor module according to a second example embodiment of the present invention includes a plurality of heat pipes 210 and a condensation portion 220.

The heat pipes 210 are spaced apart from one another along the first direction. The heat pipes 210 extend in the second direction. The condensation portion 220 is formed in a second side portion 108 of the base plate 100 opposite the first side portion 106. The condensation portion 220 connects first end portions of the heat pipes 210.

The working fluid 211 is evaporated inside each of the heat pipes 210 by heat that is transferred from the semiconductor packages 400 and 410. The evaporated working fluid 211 moves to the condensation portion 220 along the longitudinal direction (second direction) of the grooves defined by ribs 213 due to a pressure gradient inside each of the heat pipes 210.

The working fluid 211 is condensed in the condensation portion 220 due to a temperature difference at the second side portion 108 of the base plate 100. As a result, heat is transferred to the second side portion 108 of the base plate 100. Then, the condensed working fluid 211 moves to the second end portions of each of the heat pipes 210 due to a pressure gradient inside each of the heat pipes 210. As a result, heat that is generated from the semiconductor packages 400 and 410 can be effectively dissipated.

### EMBODIMENT 3

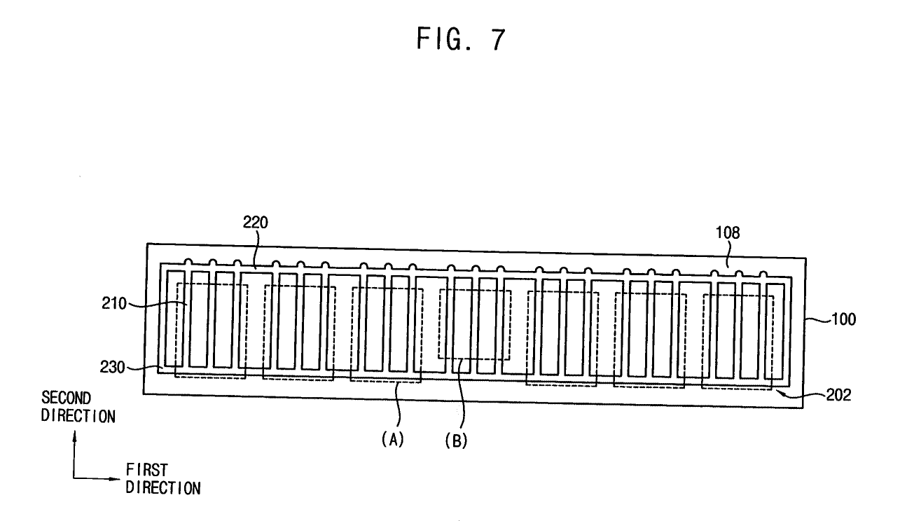

FIG. 7 is a plan view illustrating a radiation channel portion of a semiconductor module in accordance with a third example embodiment of the present invention.

The semiconductor module of the present embodiment may be substantially the same as in Embodiment 2, except for the above-described radiation channel portion 201. Thus, the same reference numerals will be used to refer to the same or similar parts as those described in Embodiment 2, and any further explanation concerning the above elements will be omitted.

Referring to FIG. 7, a radiation channel portion 202 of a semiconductor module according to a third example embodiment of the present invention includes a plurality of heat pipes 210, a condensation portion 220 and a circulation portion 230.

The heat pipes 210 are spaced apart from one another along the first direction. The heat pipes 210 extend in the second direction. The condensation portion 220 is formed in a second side portion 108 of the base plate 100 opposite the first side portion 106. The condensation portion 220 connects first end portions of the heat pipes 210.

The circulation portion 230 connects second end portions of the heat pipes 210. The circulation portion 230 also connects the condensation portion 220 to the second end portions of each of the heat pipes 210. The circulation portion 230 circulates the condensed working fluid 211 from the condensation portion 220 to the heat pipes 210.

In the embodiment illustrated in FIG. 7, the circulation portion 230 may include one heat pipe that is connected to the heat pipes 210. In another embodiment, however, the circulation portion 230 may include a plurality of heat pipes. Each of the heat pipes of the circulation portion 230 may include a plurality of ribs formed on an inner peripheral surface thereof. The ribs of the circulation portion 230 may be the same as or similar to the ribs 213 of the heat pipes 210 described with respect to Embodiment 1.

The working fluid 211 is evaporated inside each of the heat pipes 210 by heat that is transferred from the semiconductor packages 400 and 410. The evaporated working fluid 211 moves to the condensation portion 220 along the longitudinal direction (second direction) of the grooves defined by ribs 213 due to a pressure gradient inside each of the heat pipes 210.

The working fluid 211 is condensed in the condensation portion 220 due to a temperature difference at the second side portion 108 of the base plate 100. As a result, heat is transferred to the second side portion 108 of the base plate 100. Then, the condensed working fluid 211 moves to the circulation portion 230 where it circulates again to each of the heat pipes 210 through the circulation portion 230. As a result, heat that is generated from the semiconductor packages 400 and 410 can be effectively dissipated.

### EMBODIMENT 4

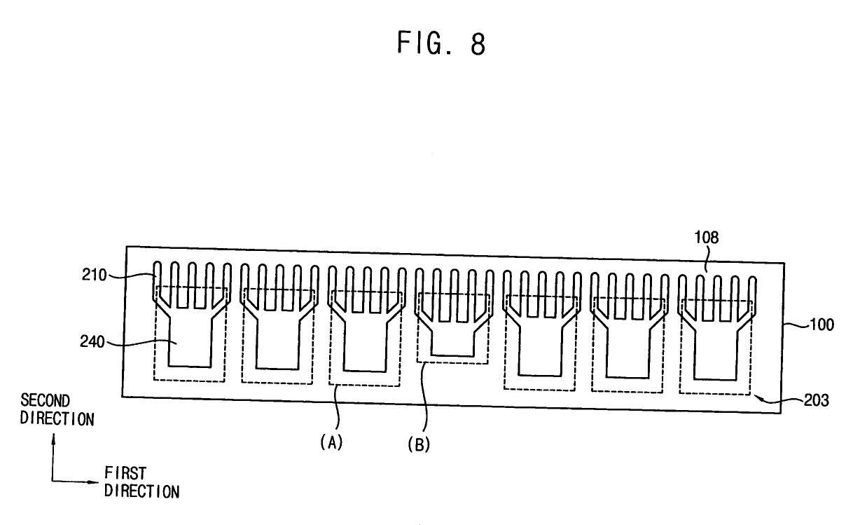

FIG. 8 is a plan view illustrating a radiation channel portion of a semiconductor module in accordance with a fourth example embodiment of the present invention.

The semiconductor module of the present embodiment may be substantially the same as in Embodiment 1, except for the above-described radiation channel portion 200. Thus, the same reference numerals will be used to refer to the same or similar parts as those described in Embodiment 1, and any further explanation concerning the above elements will be omitted.

Referring to FIG. 8, a radiation channel portion 203 of a semiconductor module according to a fourth example embodiment of the present invention includes a plurality of heat pipes 210 and a plurality of evaporation portions 240.

The locations of the evaporation portions 240 correspond to regions A and B where the semiconductor packages 400 and 410 are mounted. The working fluid 211 is evaporated in the evaporation portion 240 by heat that is transferred from the semiconductor packages 400 and 410.

The evaporation portions 240 may have a polygonal shape corresponding to the shapes of the semiconductor packages 400 and 410. For example, the evaporation portion 240 may have a rectangular shape. The evaporation portion 240 may include a plurality of ribs formed on an inner peripheral surface thereof. The ribs of the evaporation portion 240 may be the same as or similar to the ribs 213 of each of the heat pipes 210 described with respect to Embodiment 1.

Second end portions the heat pipes 210 are connected to a side portion of an evaporation portion 240. The heat pipes 210 are spaced apart from one another along the first direction. The heat pipes 210 extend in the second direction.

Heat that is generated from the semiconductor packages 400 and 410 is transferred to the working fluid 211 within the evaporation portion 240. The working fluid 211 is evaporated by heat that is transferred thereto. The evaporated working fluid 211 moves to heat pipes 210 that are respectively connected to the side portion of the evaporation portion 240.

The working fluid 211 moving to each of the heat pipes 210 moves along the longitudinal direction (second direction) of the grooves defined by ribs 213 of each of the heat pipes 210 due to a pressure gradient inside each of the heat pipes 210. Thus, the working fluid 211 moves to a first end portion from a second end portion of each of the heat pipes 210 along the second direction. Then, the working fluid 211 is condensed in the first end portion of each of the heat pipes 210 due to a temperature difference at the second side portion 108 of the base plate 100. Then, the condensed working fluid 211 moves from each of the heat pipes 210 to the evaporation portion 240 due to a pressure gradient. As a result, heat that is generated from the semiconductor packages 400 and 410 can be effectively dissipated.

### EMBODIMENT 5

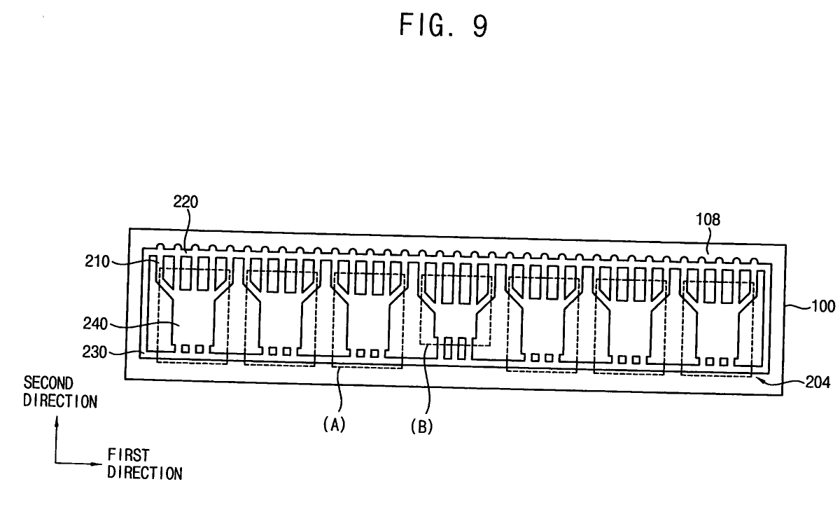

FIG. 9 is a plan view illustrating a radiation channel portion of a semiconductor module in accordance with a fifth example embodiment of the present invention.

The semiconductor module of the present embodiment may be substantially the same as in Embodiment 4, except for the above-described radiation channel portion 203. Thus, the same reference numerals will be used to refer to the same or similar parts as those described in Embodiment 4, and any further explanation concerning the above elements will be omitted.

Referring to FIG. 9, a radiation channel portion 204 of a semiconductor module according to a fifth example embodiment of the present invention includes a plurality of heat pipes 210, a condensation portion 220, a circulation portion 230 and an evaporation portion 240.

The locations of the evaporation portions 240 correspond to regions A and B where the semiconductor packages 400 and 410 are mounted. The working fluid 211 is evaporated in the evaporation portion 240 by heat that is transferred from the semiconductor packages 400 and 410.

The evaporation portions 240 may have a polygonal shape corresponding to the shapes of the semiconductor packages 400 and 410. For example, the evaporation portion 240 may have a rectangular shape. The evaporation portion 240 may include a plurality of ribs formed on an inner peripheral surface thereof. The ribs of the evaporation portion 240 may be the same as or similar to the ribs 213 of each of the heat pipes 210 described with respect to Embodiment 1.

Second end portions of the heat pipes 210 are connected to a side portion of the evaporation portion 240. The heat pipes 210 are spaced apart from one another along the first direction. The heat pipes 210 extend in the second direction.

The condensation portion 220 is formed in a second side portion 108 of the base plate 100 opposite the first side portion 106. The condensation portion 220 is connected to first end portions of the heat pipes 210.

The circulation portion 230 connects other side portions of the evaporation portions 240. The circulation portion 230 also connects the condensation portion 220 to the other side portions of the evaporation portion 240. The circulation portion 230 circulates the condensed working fluid 211 from the condensation portion 220 to the evaporation portions 240.

In the embodiment illustrated in FIG. 9, the circulation portion 230 may include one heat pipe that is connected to the evaporation portions 240. Alternatively, the circulation portion 230 may include a plurality of heat pipes. Each of the heat pipes of the circulation portion 230 may include a plurality of ribs formed on an inner peripheral surface thereof. The ribs of the circulation portion 230 may be the same as or similar to the ribs 213 of the heat pipes 210 described with respect to Embodiment 1.

Heat that is generated from the semiconductor packages 400 and 410 is transferred to the working fluid 211 within the evaporation portions 240. The working fluid 211 is evaporated by heat that is transferred thereto. The evaporated working fluid 211 moves to heat pipes 210 that are connected to the side portions of corresponding evaporation portions 240. Then, the evaporated working fluid 211 moves to the condensation portion 220 along the longitudinal direction (second direction) of the grooves defined by ribs 213 of each of the heat pipes 210 due to a pressure gradient inside each of the heat pipes 210.

The working fluid 211 is then condensed in the condensation portion 220 by a temperature difference at a second side portion 108 of the base plate 100 so that heat is transferred to the second side portion 108 of the base plate 100. Then, the condensed working fluid 211 moves to the circulation portion 230 where it circulates again to the evaporation portion 240 through the circulation portion 230. As a result, heat that is generated from the semiconductor packages 400 and 410 can be effectively dissipated.

### EMBODIMENT 6

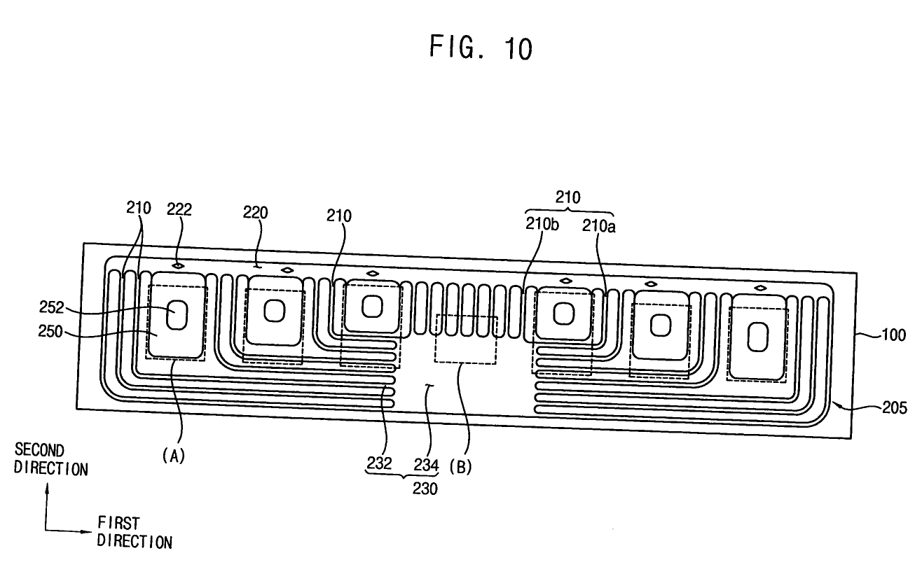

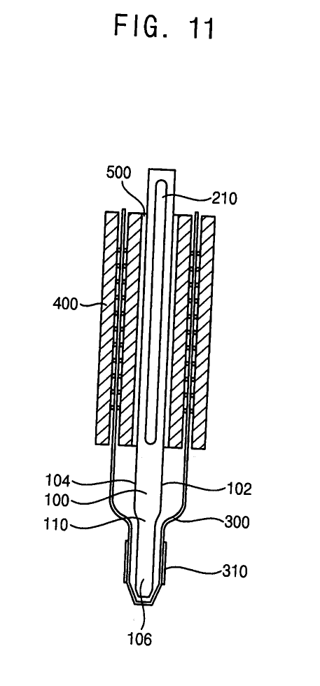

FIG. 10 is a plan view illustrating a radiation channel portion of a semiconductor module in accordance with a sixth example embodiment of the present invention.

The semiconductor module of the present embodiment may be substantially the same as in Embodiment 1, except for the above-described radiation channel portion 200. Thus, the same reference numerals will be used to refer to the same or similar parts as those described in Embodiment 1, and any further explanation concerning the above elements will be omitted.

Referring to FIG. 10, a radiation channel portion 205 of a semiconductor module according to a sixth example embodiment of the present invention includes a plurality of heat pipes 210, a condensation portion 220, a circulation portion 230 and a plurality of support portions 250.

The support portions 250 are spaced apart from one another along the first direction. Each support portion 250 is disposed between the heat pipes 210. The support portion 250 supports the radiation channel portion 205. The support portion 250 may include a cavity 252 into which the working fluid 211 is not injected. Accordingly, the support portion 250 may have a relatively lower thermal conductivity than the heat pipes 210.

In one embodiment, locations of the support portions 250 may correspond to regions A where the first semiconductor packages 400 are mounted. In another embodiment, locations of the support portions 250 may be positioned between regions A where the first semiconductor packages 400 are not mounted. Accordingly, the extent of heat dissipation of the semiconductor package may be varied by changing the position of the support portion 250.

The heat pipes 210 are spaced apart from one another along the first direction. The heat pipes 210 may be positioned between the support portions 250. The heat pipes 210 extend in the second direction.

The condensation portion 220 is formed in a second side portion 108 of the base plate 100 opposite the first side portion 106. The condensation portion 220 is connected to first end portions of the heat pipes 210. Further, a guide portion 222 may be formed in the condensation portion 220 to guide a flow of the working fluid 211.

In the illustrated embodiment, a first group of the heat pipes 210a may be positioned between the support portions 250. The first group of the heat pipes 210a may be positioned between adjacent first regions A where the first semiconductor packages 400 are mounted. A location of the second group of the heat pipes 210b may correspond to a second region B where the second semiconductor package 410 is mounted. In one embodiment, the second group of the heat pipes 210b may be positioned relatively close to one another at a location corresponding to the second region B where the second semiconductor package 410 is mounted. Accordingly, the second semiconductor package 410 (e.g., an AMB) having relatively high heat dissipation, and the first semiconductor package 400 (e.g., a CSP) may have substantially lower heat dissipation than the second semiconductor package 410.

Second end portions of the heat pipes 210 are connected to the circulation portion 230. The circulation portion 230 circulates the condensed working fluid 211 from the condensation portion 220.

In one embodiment, the circulation portion 230 may include a plurality of circulating pipes 232 and an integral portion 234. The circulating pipes 232 may be connected to corresponding ones of the second end portions of the first group of the heat pipes 210a. Each of the circulating pipes 232 may extend from a respective one of the first group of the heat pipes 210a in the first direction.

The integral portion 234 may be positioned adjacent to the second region B where the second semiconductor package 410 is mounted. First side portions of the integral portion 234 may be connected to the circulating pipes 232. A second side portion of the integral portion 234 may be connected to second end portions of the second heat pipes 210b. Accordingly, the integral portion 234 may connect the circulating pipes 232 to the second group of the heat pipes 210b.

Heat that is generated from the second semiconductor package 410 is transferred to the working fluid 211 within the second group of the heat pipes 210b. The working fluid 211 is evaporated by heat that is transferred thereto. The evaporated working fluid 211 moves to the condensation portion 220 along the longitudinal direction (second direction) of the grooves defined by ribs 213 due to a pressure gradient inside the second group of the heat pipes 210b.

Then, the working fluid 211 is guided by the guide portion 222 within the condensation portion 220 to move within the entire region of the condensation portion 220. Thus, the working fluid 211 is condensed in the condensation portion 220 by a temperature difference at the second side portion 108 of the base plate 100.

The condensed working fluid 211 moves to the first group of the heat pipes 210a between the support portions 250, and then, circulates to the integral portion 234 through the circulating pipes 232 of the circulation portion 230 that extends from the first group of the heat pipes 210a. As a result, heat that is generated from the semiconductor packages 400 and 410 can be effectively dissipated at a relatively high rate from the region (B) where the second semiconductor package 410 is mounted.

### EMBODIMENT 7

FIG. 11 is a cross-sectional view illustrating a semiconductor module in accordance with a seventh example embodiment of the present invention.

The semiconductor module of the present embodiment may be substantially the same as in Embodiment 1, except for the above-described base plate 100. Thus, the same reference numerals will be used to refer to the same or similar parts as those described in Embodiment 1, and any further explanation concerning the above elements will be omitted.

Referring to FIG. 11, a base plate 100 of a semiconductor module 11 according to a seventh example embodiment of the present invention includes a first side portion 106 having an insertion portion 110.

The insertion portion 110 may extend between the first contacts 310 and have a predetermined thickness that is less than the thickness of the base plate 100. Accordingly, a step region may exist between side faces of the insertion portion 110 and the first and the second side faces 102 and 104 of the base plate 100. That is, side faces of the insertion portion 110 are not coplanar with the first or second side faces 102 and 104 of the base plate 100. Accordingly, the insertion portion 110 may be inserted into a socket of a circuit board (not illustrated) where the semiconductor module 11 is mounted. It will be appreciated that the particular thickness and shapes of the insertion portion 110 may be varied according to, for example, the socket of the circuit board.

### EMBODIMENT 8

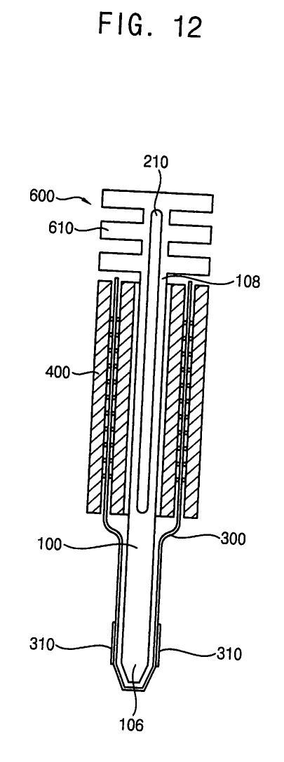

FIG. 12 is a cross-sectional view illustrating a semiconductor module in accordance with an eighth example embodiment of the present invention.

The semiconductor module of the present embodiment may be substantially the same as in Embodiment 1, except for the above-described base plate 100. Thus, the same reference numerals will be used to refer to the same or similar parts as those described in Embodiment 1, and any further explanation concerning the above elements will be omitted.

Referring to FIG. 12, a base plate 100 of a semiconductor module 12 according to an eighth example embodiment of the present invention includes an expansion portion 600. The expansion portion 600 may include a plurality of fins 610.

The expansion portion 600 may be formed at the second side portion 108 of the base plate 100. For example, the expansion portion 600 may extend from the base plate 100. The fins 610 may extend from the expansion portion 600 away from both faces of the base plate 100. It will be appreciated that certain features such as the shapes, structure, material, etc., of the fin 610 may be controllably selected to provide an effective heat transfer of the semiconductor module 12.

The expansion portion 600 may effectively dissipate heat that is transferred from the working fluid 211. The expansion portion 600 may provide the semiconductor module 12 with additional interfaces to thereby enhance convection of heat away from the semiconductor module 12.

Heat is transferred from the working fluid 211 to the fins 610 of the expansion portion 600. Accordingly, heat may dissipate outside through the fins 610 due to, for example, convection of air flowing over the fins 610.

### EMBODIMENT 9

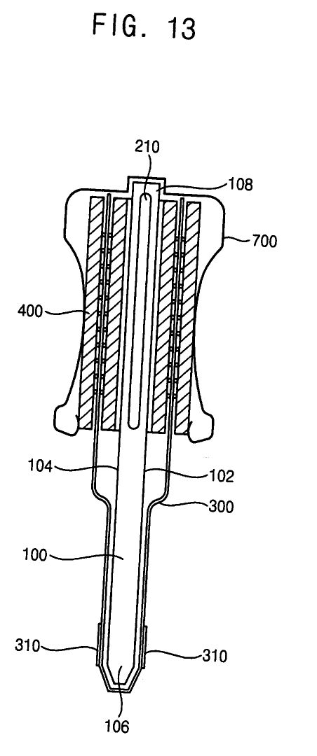

FIG. 13 is a cross-sectional view illustrating a semiconductor module in accordance with a ninth example embodiment of the present invention.

The semiconductor module of the present embodiment may be substantially the same as in Embodiment 1, except for the presence of a radiation clip 700. Thus, the same reference numerals will be used to refer to the same or similar parts as those described in Embodiment 1, and any further explanation concerning the above elements will be omitted.

Referring to FIG. 13, a semiconductor module 13 according to a ninth example embodiment of the present invention further includes a radiation clip 700.

The radiation clip 700 clamps around the semiconductor packages 400. The radiation clip 700 may make contact with the outermost semiconductor packages that are mounted over the first and second side faces 102 and 104 of the base plate 100. Further, the radiation clip 700 may contact the second side portion 108 of the base plate 100 so that the radiation clip 700 is thermally connected to the base plate 100.

In one embodiment, the radiation clip 70 may include a thermally conductive material such as metal.

According to example embodiments of the present invention described above, a semiconductor module includes a radiation channel portion formed inside a base plate on which semiconductor packages are mounted. The radiation channel portion includes a plurality of heat pipes having a working fluid injected therein. The working fluid is repeatedly evaporated and condensed by heat that is transferred from the semiconductor packages to the base plate.

As will be appreciated, embodiments of the present invention may be practiced in many ways. What follows below is a non-limiting discussion of some example embodiments that may be practiced in accordance with the principles of the present invention.

According to one aspect of the present invention, a semiconductor module includes a base plate, a circuit substrate, a plurality of semiconductor packages and a radiation channel portion. The circuit substrate is adhered to at least one side face of the base plate. The semiconductor packages are mounted on a surface or both surfaces of the circuit board. The radiation channel portion is formed inside the base plate. The radiation channel portion includes a plurality of heat pipes having a working fluid being injected into the heat pipes, the working fluid being repeatedly evaporated and condensed by heat that is transferred from the semiconductor packages to dissipate the heat outside through flowing of the working fluid.

In one example embodiment, each of the heat pipes may include a plurality of grooves formed on an inner peripheral surface of each of the heat pipes, the grooves extending in a longitudinal direction of the heat pipes.

In one example embodiment, the base plate may include a first side portion configured to be inserted into a socket of a circuit board, and the circuit substrate is adhered to the base plate, a portion of the circuit substrate being conformally wound around the first side portion of the base plate.

The circuit substrate may include a plurality of contacts that are positioned adjacent to the first side portion of the base plate, the contacts being electrically connected to the circuit board.

The first side portion includes an insertion portion having a stepped portion relatively lower than both side faces of the base plate.

In one example embodiment, the semiconductor packages may be adhered to the base plate by a heat transfer layer including thermal interface material (TIM).

In one example embodiment, the base plate may extend in a first direction and the heat pipes may extend in a second direction perpendicular to the first direction.

In another example embodiment, the radiation channel portion may further include a condensation portion that is connected to second end portions of the heat pipes, the working fluid being condensed in the condensation portion. Further, the radiation channel portion may further include a circulation portion that connects the condensation portion to first end portions of the heat pipes, the working fluid being circulated by the circulation portion.

In still yet another example embodiment, the radiation channel portion may further include an evaporation portion, the evaporation portion being positioned corresponding to a region where the semiconductor package is mounted, the working fluid being condensed in the condensation portion.

In still yet another example embodiment, the radiation channel portion may include a plurality of support portions spaced apart from one another along a longitudinal direction of the base plate, the support portion including a cavity into which the working fluid is not injected; a plurality of heat pipes disposed between the support portions; a condensation portion connected to second end portions of the heat pipes, the working fluid being condensed in the condensation portion; and a circulation portion connected to first end portions of the heat pipes.

In this case, a first group of the heat pipes may be positioned adjacent to a first region where a first semiconductor package is mounted and a second group of the heat pipes may be positioned corresponding to a second region where a second semiconductor package is mounted. The circulation portion may include a plurality of circulation pipes extending from the first group of the heat pipes in the longitudinal direction of the base plate, and an integral portion connected to the circulation pipes, the integral portion connecting the circulating pipes to the second group of the heat pipes.

In still yet another example embodiment, the base plate may further include an expansion portion extending from a side portion of the base plate and dissipating heat that is transferred from the working fluid. The expansion portion may include a plurality of fins.

The semiconductor module may further includes a radiation clip making contact with and clamping around the outermost semiconductor packages, the radiation clip being thermally connected to the base plate.

According to the present invention, a semiconductor module includes a radiation channel portion formed inside a base plate on which semiconductor packages are mounted. The radiation channel portion includes a plurality of heat pipes having a working fluid being injected into the heat pipes, the working fluid being repeatedly evaporated and condensed by heat that is transferred from the semiconductor packages to the base plate.

The working fluid within each of the heat pipes is evaporated by the heat, and then the working fluid moves along a longitudinal direction of the heat pipes. Then, the working fluid is condensed by a temperature difference between the inside and outside of the heat pipes to dissipate the heat outside, to thereby improve the heat dissipation efficiency.

Therefore, the radiation channel portion may provide an efficient and reliable semiconductor module having improved heat transfer and radiation performance.

The foregoing is illustrative of embodiments of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A semiconductor module comprising:
a base plate;
a circuit substrate coupled to a side face of the base plate;
a first semiconductor package mounted on the circuit substrate; and
a radiation channel portion inside the base plate, the radiation channel portion including at least one heat pipe containing a working fluid, wherein the at least one heat pipe containing the working fluid is configured to transfer heat generated by the first semiconductor package.

2. The semiconductor module of claim 1, further comprising a plurality of ribs formed on an inner peripheral surface of the at least one heat pipe, the plurality of ribs defining a plurality of grooves therebetween that extend in a longitudinal direction of the at least one heat pipe.

3. The semiconductor module of claim 1, wherein the radiation channel portion further comprises a condensation portion connected to a first end portion of the at least one heat pipe at a location where the working fluid is condensable.

4. The semiconductor module of claim 3, wherein the radiation channel portion further comprises a circulation portion connected to a second end portion of the at least one heat pipe, wherein the working fluid is circulatable to the at least one heat pipe from the condensation portion by the circulation portion.

5. The semiconductor module of claim 1, wherein the working fluid is condensable at a first end portion of the at least one heat pipe and wherein the radiation channel portion further comprises:
an evaporation portion connected to a second end portion of the at least one heat pipe, wherein a location of the evaporation portion corresponds to a region where the first semiconductor package is mounted on the circuit substrate.

6. The semiconductor module of claim 1, wherein the at least one heat pipe comprises a plurality of heat pipes and wherein the radiation channel portion further comprises:
a support portion adjacent to at least some of the plurality of heat pipes, the support portion including a cavity that does not contain working fluid, wherein a location of the support portion corresponds to a region where the first semiconductor package is mounted on the circuit substrate;
a condensation portion connected to first end portions of the plurality of heat pipes at a location where the working fluid is condensable; and
a circulation portion connected to second end portions of the plurality of heat pipes.

7. The semiconductor module of claim 6, further comprising a second semiconductor package mounted on the circuit substrate, wherein
a first group of the plurality of heat pipes are adjacent to the support portion,
a second group of the plurality of heat pipes are positioned at a location corresponding to a region where a second semiconductor package is mounted on the circuit substrate, and
the circulation portion comprises:
a plurality of circulation pipes extending from the first group of the heat pipes in the longitudinal direction of the base plate; and
an integral portion connecting the circulating pipes to the second group of the plurality of heat pipes.

8. The semiconductor module of claim 1, wherein the base plate further comprises an expansion portion extending from a side portion of the base plate configured to dissipate the transferred heat.

9. The semiconductor module of claim 8, wherein the expansion portion comprises a plurality of fins.

10. The semiconductor module of claim 1, wherein
the base plate comprises a first side portion configured to be inserted into a socket of a circuit board, and
a portion of the circuit substrate is wound around the first side portion of the base plate.

11. The semiconductor module of claim 10, wherein the circuit substrate comprises a plurality of contacts that are positioned adjacent to the first side portion of the base plate, the contacts being electrically connectable to the circuit board.

12. The semiconductor module of claim 10, wherein the first side portion comprises an insertion portion, wherein a side face of the insertion portion is not coplanar with the side face of the base plate.

13. The semiconductor module of claim 1, wherein the semiconductor packages are thermally coupled to the base plate by a heat transfer layer including thermal interface material.

14. The semiconductor module of claim 1, further comprising a radiation clip clamping around an outermost surface of a semiconductor package counted on the circuit substrate, the radiation clip being thermally connected to the base plate and the outermost surface of a semiconductor package.

15. The semiconductor module of claim 1, wherein the base plate extends in a first direction and the heat pipe extends in a second direction perpendicular to the first direction.
